(19) United States
(12) Patent Application Publication
(10) Pub. No.: US 2006/0240580 A1
(43) Pub. Date: Oct. 26, 2006

(54) Method for evaluating reproduced images of wafers

(76) Inventor: Detlef Michelsson, Wetzlar-Naunheim (DE)

Correspondence Address: SIMPSON & SIMPSON, PLLC, 5555 MAIN STREET, WILLIAMSVILLE, NY, 14221-5406, US

(21) Appl. No.: 10/564,120

(22) PCT Filed: May 11, 2004
(86) PCT No.: PCT/EP04/50758

§ 371 Date: Apr. 27, 2006

(30) Foreign Application Priority Data
Jul. 14, 2003 (DE) 103 31 686.8

(51) Int. Cl. H01L 21/66; G01R 31/26

(52) U.S. Cl. 438/14

(57) ABSTRACT

Method for evaluating recorded images of wafers is disclosed. The recording of an image of at least one reference wafer is followed by the determination and representation, on a user interface, of the radial distribution of the measured values of the reference wafer as a radial homogeneity function. A radially dependent sensitivity profile is changed while taking into account the measured radial homogeneity function of the reference wafer. At least one parameter of the sensitivity profile is varied whereby a learned sensitivity profile is determined visually from the comparison with the radial homogeneity function.

The invention relates to a method for evaluating recorded wafer images.

In semiconductor production, during the fabrication process, wafers are sequentially processed in a multitude of processing steps. With increasing integration density, the requirements on the quality of the structures formed on the wafers increase. To be able to check the quality of the structures formed and to be able to find possible defects, corresponding requirements are placed on the quality, accuracy and reproducibility of the equipment components and processing steps handling the wafer. This means that in the production of a wafer with the multitude of processing steps and multitude of photoresist or similar layers that have to be applied, reliable and early detection of defects is particularly important. In the optical identification of defects it is necessary to take into account the systematic defects owing to thickness fluctuations during the coating of the semiconductors so as to avoid the marking of sites on the semiconductor wafer that do not contain defects.

Macroscopic images of semiconductor wafers show that the homogeneity of the layers changes radially. During coating, in particular, changes in homogeneity appear in the regions distant from the center point of the wafer. If for the evaluation of recorded wafer images, as before, a uniform sensitivity is used over the entire radius of the wafer, it can happen that the deviations at the mar-gins are always detected, but the internal defects (near the center point of the wafer) are not. If a high sensitivity is selected to detect defects in homogeneous regions with certainty, then more pronounced detection errors occur in the marginal regions, because the nonhomogeneous marginal regions cannot always be evaluated as defects. To prevent this, the marginal regions can be entirely disregarded. In this case, however, no real defects are found in these regions. If, on the other hand, one selects a lower sensitivity, no false defect detections are made, but the defects in the homogeneous regions cannot be found.

The object of the invention is to provide a method whereby an unequivocal detection of defects is possible while taking into account the nonhomogeneities on the surface of a wafer.

This objective is reached by means of a method having the features described in claim 1.

It is particularly advantageous if first an image of at least one reference wafer is recorded. Based on the recorded image, the radial distribution of the measurements made on the reference wafer is determined and represented on a user interface as a radial homogeneity function. A radially-dependent sensitivity profile is modified taking into account the radial homogeneity function of the reference wafer and varying at least one parameter of the sensitivity profile thereby visually deter-mining a learned sensitivity profile from the comparison with the radial homogeneity function. Defects on at least one other wafer are determined from a comparison of the learned radial sensitivity profile of the reference wafer and the measured radial distribution of the homogeneity function of the at least one other wafer. The defect on the wafer is found by the fact that the measured radial distribution of the homogeneity function falls below the learned sensitivity profile. The defect found is marked on a graphic representation of the at least one other wafer. The learned sensitivity profile depends on the distance from the center point of the wafer. This de-pendence is a result of the dependence arising from the wafer production processes. For sub-sequent lithographic processing, layers are applied to the wafer by a spinning process. This alone causes thickness fluctuations of the layer or layers which are to be taken into account in the detection of defects.

On the user interface, there are present several different profile forms that can be chosen by the user for the determination of the learned sensitivity profile.

Three different profile forms that can be selected by the user to determine the learned sensitivity profile have been found to be particularly well suited. Of these, the first profile form is inde-pendent of the radial position on the wafer. A second profile form consists of a first and a second section of which only one can be modified in terms of its slope. A third profile form is provided which has a first, second and third section, the level of each section being independently changeable.

At least one parameter can be varied in order to adapt the sensitivity profile to the radial homogeneity function of a wafer. At least one parameter stands for the radial position of a transition between two sections of the sensitivity profile differing in slope. Another parameter defines the level of the sensitivity profile, it being possible to set at least three levels of the sensitivity profile. The level of the sensitivity profile is based on the level of the radial homogeneity function. The setting of the level or of the sections with the different slopes can be changed by means of a slider.

In the drawing, the object of the invention is represented schematically and in the following is explained by reference to the figures, of which:

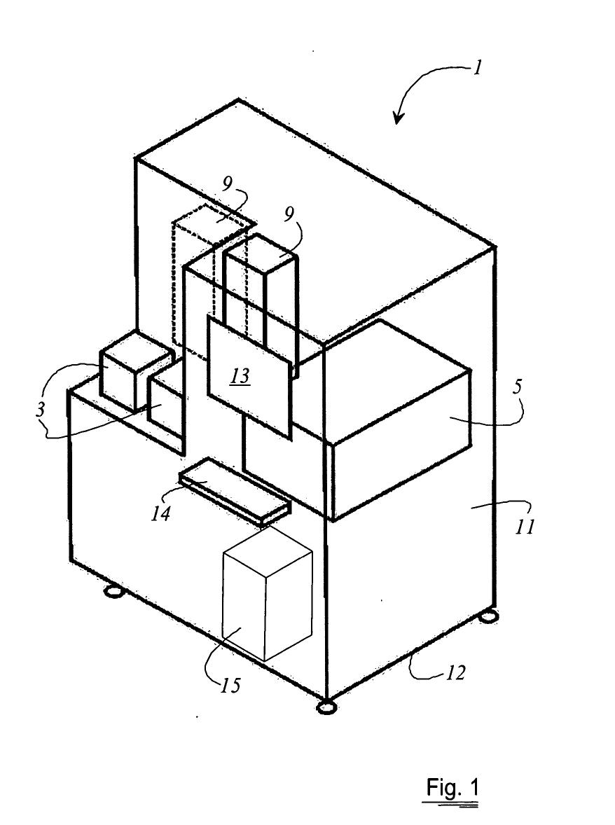

FIG. 1 is a schematic representation of a system for detecting defects on wafers;

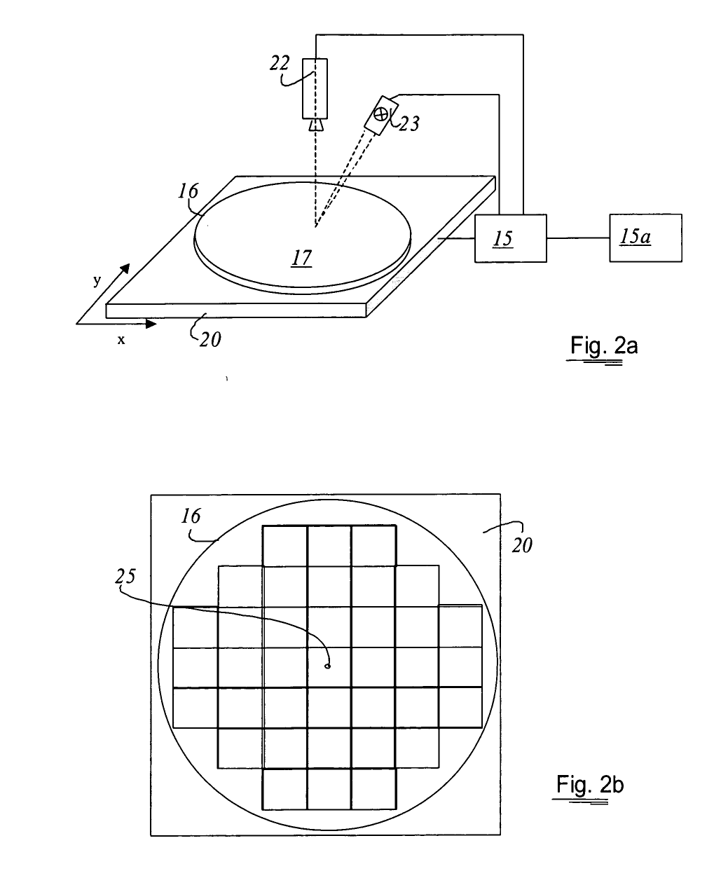

FIG. 2a is a representation of the type of image recording or image data of a wafer;

FIG. 2b shows a schematic top view of a wafer;

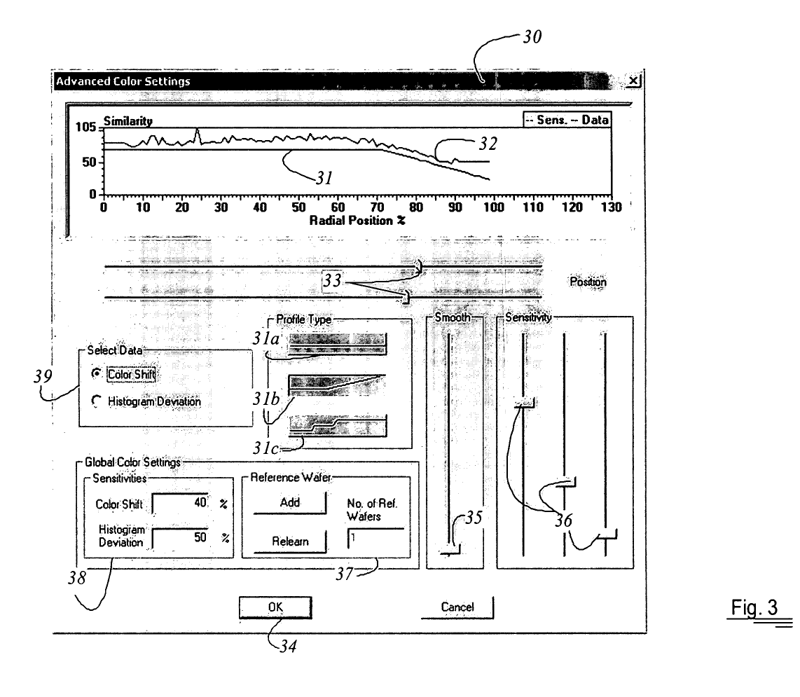

FIG. 3 shows a version of a user interface for parameter input for establishing a sensitivity profile for the color fluctuations on the surface of a wafer;

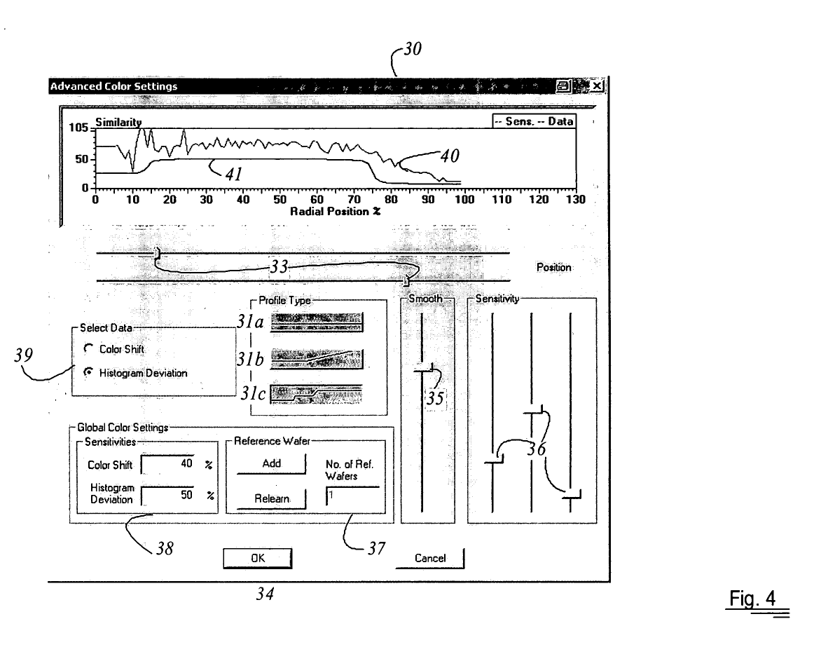

FIG. 4 shows a version of a user interface for parameter input for establishing a sensitivity profile for the radial deviation of the data from a histogram.

FIG. 1 shows a system for detecting defects on wafers. System 1 consists, for example, of at least one cassette element 3 for the semiconductor substrates or wafers. Images or image data of the individual wafers are recorded in a measuring unit 5. A transport mechanism 9 is provided between cassette element 3 for the semiconductor substrates or wafers and measuring unit 5. System 1 is enclosed by a housing 11, said housing 11 defining a bottom surface 12. Integrated into system 1 is also a computer 15 which acquires and processes the images or image data of the individual wafers measured. System 1 is provided with a display 13 and a keyboard 14. By means of keyboard 14, the user can input data for controlling the system or also parameters for evaluating the image data of the individual wafers. On display 13, several user interfaces are displayed for the user.

FIG. 2a shows a schematic view of the manner in which the images and/or image data of a wafer 16 are acquired. Wafer 16 is placed on stage 20 which in housing 11 can be displaced in a first direction X and a second direction Y. The first direction X and the second direction Y are perpendicular to one another. Above surface 17 of wafer 16 there is provided an image-taking device 22 the image field of image-taking device 22 being smaller than the total surface 17 of wafer 16. To be able take in the entire surface 17 of wafer 16 with the image-taking device 22, wafer 16 is scanned in meandering fashion. The individual successively acquired image fields are combined into an overall image of surface 17 of wafer 16. This is also done by the computer 15 provided in housing 11. In this practical example, to create a relative movement between stage 20 and image-taking device 22, an x-y scanning stage is used which can be displaced in the coordinate directions x and y. Camera 22 is firmly installed above stage 20. Naturally, viceversa, stage 20 can be firmly installed and the image-taking device 22 for taking images moved over wafer 16. A combination in which camera 23 is moved in one direction and stage 20 is moved in the direction perpendicular thereto is also possible.

Wafer 16 is illuminated with an illumination device 23 which illuminates at least those regions on wafer 16 that correspond to the image field of image-taking device 22. As a result of the concentrated illumination which in addition can be pulsed with a photoflash lamp, on-the-fly image taking is possible, namely stage 20 or image-taking device 22 can be displaced without stopping for image taking. In this manner, a high wafer throughput is possible. Naturally, it is also possible to stop the relative movement between stage 20 and image-taking device 22 for each image taking and to illuminate the entire surface 17 of wafer 16. Stage 20, image-taking device 22 and illumination device 23 are controlled by computer 15. The images taken can be stored by computer 15 in a memory 15a and can optionally be recalled therefrom.

FIG. 2b shows a top view of a wafer 16 resting on a stage 20. Wafer 16 has a center point 25. Layers are applied onto wafer 16 which in a subsequent processing step are structured. A structured wafer comprises a multiplicity of structured elements.

FIG. 3 shows a version of a user interface 30 for parameter input to establish a sensitivity profile 31 for the color fluctuations on surface 17 of wafer 16. On user interface 30, the color fluctuation is plotted as a function 32 of the radius of wafer 16. The deviations are evaluated, and the fluctuations of function 32 are viewed as a measure of the change in color of surface 17 of wafer 16 as seen from center point 25 of wafer 16. Function 32 or the curve is obtained from the minimum of all values measured at a distance from center point 25 or of all measured values lying on a radius. To adapt sensitivity profile 31 to function 32, the user has at his disposal several different profile forms 31a, 31b and 31c whereby he can determine and establish a learned sensitivity profile 31. Sensitivity profile 31 thus determined is used for the determination and characterization of defects on other wafers of a lot. In the production or in the application of the learned sensitivity profile 31, said sensitivity profile is compared with the measured values of different wafers of a lot. A defect is characterized when a measured value falls below the learned sensitivity profile 31. The user interface 30 shown in FIG. 3 appears on display 13, and the user can make the required inputs by means of keyboard 14. After the user has chosen a first, second or third profile form 31a, 31b or 31c, he can change them by a visual comparison with function 32. The changing of a radially dependent sensitivity profile 31 while taking into account the radial function 32 of the reference wafer is accomplished in that at least one parameter of the selected profile form is varied, a learned sensitivity profile thereby being determined visually. In other words, the user can decide visually on the display whether he is satisfied with the adaptation of sensitivity profile 31 to the particular function in question. On user interface 30, positioning elements 33 are shown to the user. The positioning elements 33 are shown under the graphic representation of sensitivity profile 31 and function 32. The location of positioning elements 33 can be changed, for example, with the aid of a mouse (not shown). The second and third profile form 31b and 31c can have at least one section that is provided with a slope different from that of the rest of the profile form. In the version shown in FIG. 3, there are provided two sections in profile form 31 which differ in their slope. In FIG. 3, the transition from one section to the other is fixed by one of positioning elements 33. On display 30, a setting element 35 is provided for the user for smoothing the sensitivity profile 31. Moreover, additional setting elements 36 for the sensitivity of sensitivity profile 31 are available to the user. By means of the multiplicity of setting elements 33, 35 and 36, the user can adapt sensitivity profile 31 to function 32 and on display 13 observe the changes that have taken place and evaluate them for their relevance. User interface 30 also provides the user with a selection field 37 whereby he can add the sensitivity profiles of other reference wafers to the existing learned sensitivity profiles. Furthermore, it is possible for the user to use a new wafer as reference wafer and to establish for it a new learned sensitivity profile. In an input field 38, the user obtains the information about the general settings concerning the color changes on a wafer. The settings comprise the color shift and the deviation from a histogram. In a selection field 39, the user can see which data selection was made or set. In the version represented in FIG. 3, the color shift was selected. The user confirms his input or settings by depressing an OK button 34.

FIG. 4 shows a version of a user interface for parameter input for establishing a learned sensitivity profile, function 40 representing the radial calibration of the histogram data. The representation of the user interface in FIG. 4 is comparable to the representation in FIG. 3. Identical reference numerals are used to indicate the same components. For the adaptation of a sensitivity profile 41 to radial function 40, a profile form 31 was selected which has three sections differing in slope and/or level. The user evaluates the display visually to see if he is satisfied with the adaptation of sensitivity profile 31 to the particular function in question. Positioning elements 33 shown on user interface 30 can be displaced by the user so that they mark the position of the transitions be-tween the individual sections. The representation of positioning elements 33 is shown under the graphic representation of sensitivity profile 41 and function 40. In addition, the other setting ele-ments 36 for the sensitivity of sensitivity profile 31 are made available to the user. With the multiplicity of setting elements 33, 35 and 36, the user can adapt sensitivity profile 31 to function 32 and on the display 13 observe the changes that have taken place and evaluate them for their relevance.

1. A method for determining defects in recorded wafer images by the steps, which comprise:
(i) recording an image of at least one reference wafer,
(ii) determining and representing on a user interface a radial distribution of values measured on the at least one reference wafer as a radial homogeneity function, and
(iii) changing a radially dependent sensitivity profile while taking into account the radial homogeneity function of the at least one reference wafer by varying at least one parameter of the sensitivity profile, a learned sensitivity profile being determined visually by comparison with the radial homogeneity function.

2. The method as defined in claim 1, wherein the determination of defects in said recorded wafer images is carried out on at least one other wafer by comparison between the learned sensitivity profile of the at least one reference wafer with the measured radial distribution of the homogeneity function of the at least one other wafer, a defect being determined from the comparison of the measured radial distribution of the homogeneity function with the learned sensitivity profile.

3. The method as defined in claim 2, wherein the defect is determined by measuring the radial distribution of the homogeneity function falling below the learned sensitivity profile and marking a graphic representation of the at least one other wafer.

4. The method as defined in claim 1, wherein the learned sensitivity profile depends on the distance from a center point of the wafer.

5. The method as defined in claim 1, wherein several different profile forms can be selected to determine the learned sensitivity profile.

6. The method as defined in claim 5, wherein three different profile forms are selected to determine the learned sensitivity profile.

7. The method as defined in claim 1, wherein a first profile form is selected independent of the radial position on the wafer.

8. The method as defined in claim 7, wherein a second profile form is selected and comprises a first and a second section, at least one of which can be varied in slope.

9. The method as defined in claim 8, wherein a third profile form is provided having a first, second and third sections of which at least one can be varied in slope.

10. The method as defined in claim 1, wherein at least one parameter is changed so as to adapt the sensitivity profile to the radial homogeneity function of a wafer.

11. The method as defined in claim 10, wherein the least one parameter defines the radial position of a transition between two sections of the sensitivity profile differing in slope.

12. The method as defined in claim 10, wherein the sensitivity profile comprises at least three levels of settings and a parameter defines the level of the sensitivity profile.

13. The method as defined in claim 12, wherein the setting of the level can be changed by means of a slider.

14. The method as defined in claim 1, wherein several learned sensitivity profiles are combined.

15. The method as defined in claim 1, wherein a learned sensitivity profile can be replaced by a relearned sensitivity profile at any time.
